(19) United States
(12) Patent Application Publication
(10) Pub. No.: US 2016/0324026 A1
(43) Pub. Date: Nov. 3, 2016

(54) Device Casing Including Layered Metals

(71) Applicant: HEWLETT-PACKARD DEVELOPMENT COMPANY, L.P., Houston, TX (US)

(72) Inventors: YU-CHUAN KANG, Taipei City (TW); KUAN-TING WU, Taipei City (TW)

(73) Assignee: Hewlett-Packard Development Company, L.P., Houston, TX (US)

(21) Appl. No.: 15/105,148

(22) PCT Filed: Jan. 21, 2014
(86) PCT No.: PCT/US2014/012260

§ 371 Date: Jun. 16, 2016

(51) Int. Cl. H05K 5/04; C09D 5/44; C25D 11/02; C25D 13/22; C25D 13/20

(52) U.S. Cl. CPC H05K 5/04; C25D 13/22; C25D 13/20; C25D 11/026; C09D 5/4411; B05D 1/02

(57) ABSTRACT

A casing for electrical devices is provided. The casing comprises an intermediate layer of less reactive light metal 120 sandwiched between a substrate layer of more reactive light metal 130 and a coat layer 110.

### BACKGROUND

Devices such as mobile phones, tablets and portable (laptop or palm) computers see generally provided with a casing. The casing typically provides a number of functional features, protecting the device from damage.

Consumers are also interested in the aesthetic properties of the casing such as the look, colour, texture and style. In addition, devices such as mobile phones, tablets and portable computers are typically designed for hand held functionality, thus the consumer may also consider the weight of the device and the feel of the casing by which they hold the device.

### BRIEF DESCRIPTION OF DRAWINGS

By way of non-limiting examples, device casings and processes of manufacturing such casings according to the present disclosure will be described with reference to the following drawings in which

FIG. 1(a) is a perspective view of an example casing for a device

FIG. 1(b) is a cut-away perspective view of the casing of FIG. 1(a)

FIG. 1(c) is a sectional side view of the casing of FIG. 1(b)

FIG. 2(a) is a sectional side view of an example casing with a synthetic fibre layer in between a substrate layer and an intermediate layer

FIG. 2(b) is a sectional side view ox an example casing with a synthetic fibre layer in between a coat layer and an intermediate layer

FIG. 2(c) is a sectional side view of an example casing with synthetic fibre layer on the substrate layer

FIG. 3 is a sectional side view of an example casing with an intermediate layer on either side of the substrate layer

FIG. 4(a) is a sectional side view of an example casing with coat on both the intermediate layer and the substrate layer

FIG. 4(b) is a sectional side view of the example casing of FIG. 4(a) with an additional coat layer

FIG. 4(c) is a sectional side view of the example casing of FIG. 4(b) with a synthetic fibre layer between the coat layer and the additional coat layer

FIG. 5 is a flow diagram illustrating an example method of manufacturing an electrical device casing

In the drawings, like reference numerals represent the same feature in multiple drawings

### DETAILED DESCRIPTION

The present disclosure describes casings for devices, such as electrical devices. The casing of this example comprises an intermediate layer of light metal sandwiched between a substrate layer of reactive light metal and a coat layer. The light metal of the intermediate layer has lower reactivity to the reactivity of the light metal in the substrate layer.

Light metals are metals of low atomic weight. While the cut-off between light metals and heavy metals varies, metals such as lithium, beryllium, sodium, magnesium and aluminium are always considered as light metals.

Reactivity of light metal is regarded by its ability to oxidize and is measured as the oxidation potential. A metal of high reactivity and hence a high value of oxidation potential implies a greater tendency for oxidation to occur relative to a metal of low reactivity or low oxidation potential value. Physically, light metal of increased level of reactivity or oxidation potential can be characterised by reactive surfaces with lots of open porous structures for rapid oxidization.

By forming an intermediate layer of less reactive light metal on the more reactive light metal, less surface treatments are required to achieve high performance surface finishing.

Furthermore, in some examples the safety concerns in treating the reactive light metal are eliminated while still retaining the benefits of being light enough in weight; to be carried with the device by a user.

For example magnesium and its alloys are classified as more reactive light metals. While magnesium and its alloys have many physical properties suitable for use in casings, such as strength and light weight, magnesium and its alloys are volatile and thus require numerous surface treatments before the final finishing/coat. The disclosed casings overcome the volatility of magnesium and its alloys and provide for a greater selection of coats to provide attractive or high performance surface finishing.

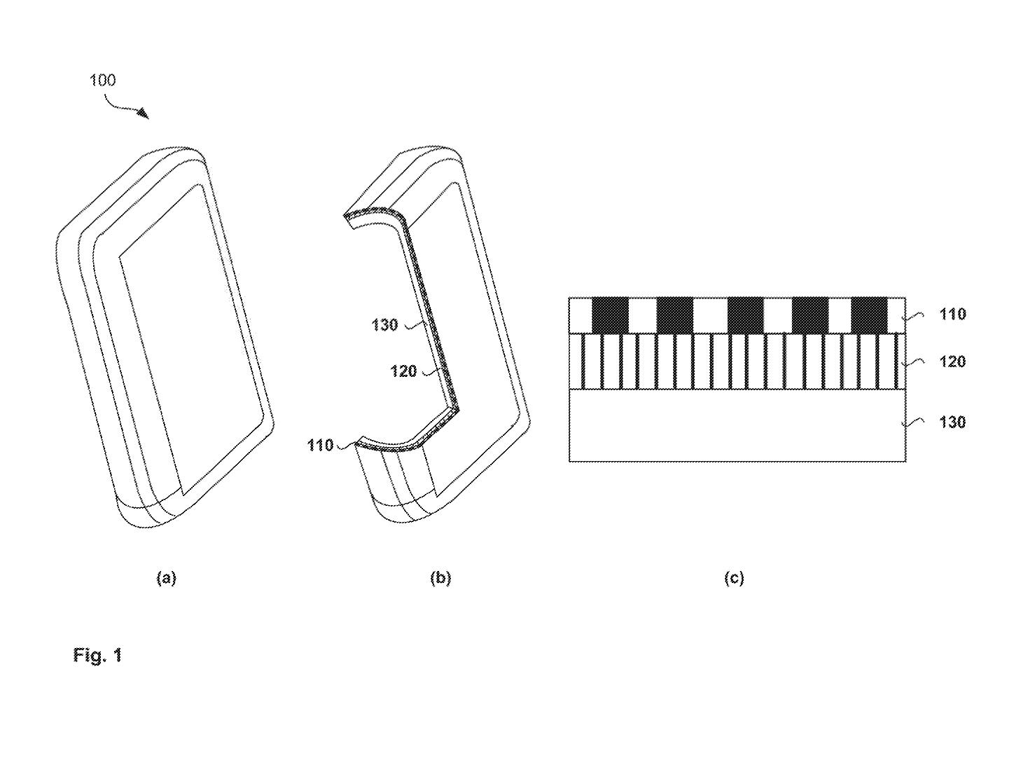

FIG. 1(a) illustrates an example casing 100 of a device, in this example a smart phone. The layers 110, 120 and 130 that form the casing 100 are shown in the cut-away perspective view of FIG. 1(b) and enlarged in FIG. 1(c).

Referring to FIGS. (b) and 1(c), the substrate layer 130 is a reactive light metal that has a higher oxidation potential relative to the oxidation potential of the light metal in the intermediate layer 120. The substrate layer 130 can be, for example, magnesium alloys and magnesium lithium alloys, where oxidation potential for magnesium is approximately 2.4 V. The intermediate layer 120 can be, for example, aluminium (oxidation potential value of approximately 1.7 V), magnesium aluminium, titanium, niobium or alloys thereof.

The casing 100 for electrical devices can also be considered to comprise of an inner base, a middle lamination and an outer finish, where the inner base is the substrate layer 130, middle lamination is the intermediate layer 120 and the outer finish is the coating layer 110.

The composite of two light metal layers comprising of a substrate layer 130 and an intermediate layer 120 of lower reactivity than the substrate layer can be formed using existing methods, such as metal inter-diffusion process and sputtering. Metal inter-diffusion process is generally a cheaper option that offers control over thickness of the light metal.

Depending on the desired properties of the coat 110, various types of coat can be formed onto the intermediate layer 120, for example metal oxide coat, electrophoretic coat, film coat and spray coat. The properties of the coat 110 may include visual, tactual and textural effects, functional properties such as UV-protection, anti-fingerprinting or anti-bacterial capability, as well as physical properties such as hardness, durability and resistance to abrasion.

As will be shown by the examples below, the coat layer 110 can be directly on the intermediate layer 120 or may be separately with further layers. Again, the intermediate layer 120 and the substrate layer 130 may be directly adjacent or may be separated by further layers.

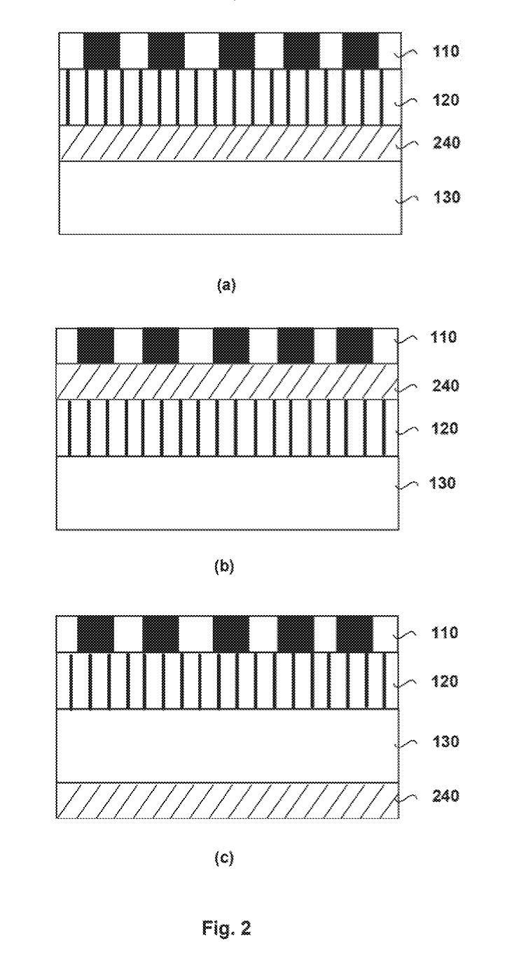

FIGS. 2(a), 2(b) and 2(c) illustrate examples of casing 100 with different configurations of a synthetic fibre layer 240. In FIG. 2(a) the synthetic fibre layer 240 is formed in between the substrate layer 130 and the intermediate layer 120. In FIG. 2(b) the synthetic layer is formed between the intermediate layer 120 and the coat layer 110. Finally, in FIG. 2(c) the synthetic layer 240 is formed on the side of the substrate layer 130, in this example on the underside of the substrate layer 130.

The addition of the synthetic fibre layer into the existing layered composite structure of FIG. 1(c) increases the mechanical strength of the casing.

Referring to FIG. 2, the synthetic fibre layer 240 is formed by press forming technologies.

Example of the synthetic fibre layer 240 includes: woven/unidirectional glass fibre, woven/unidirectional carbon fibre, carbon nanotubes, ceramic fibre, silicon carbide fibre, aramid fibre, metal fibre, or the combination thereof by thermoplastic resins and semi-curing thermoset resins.

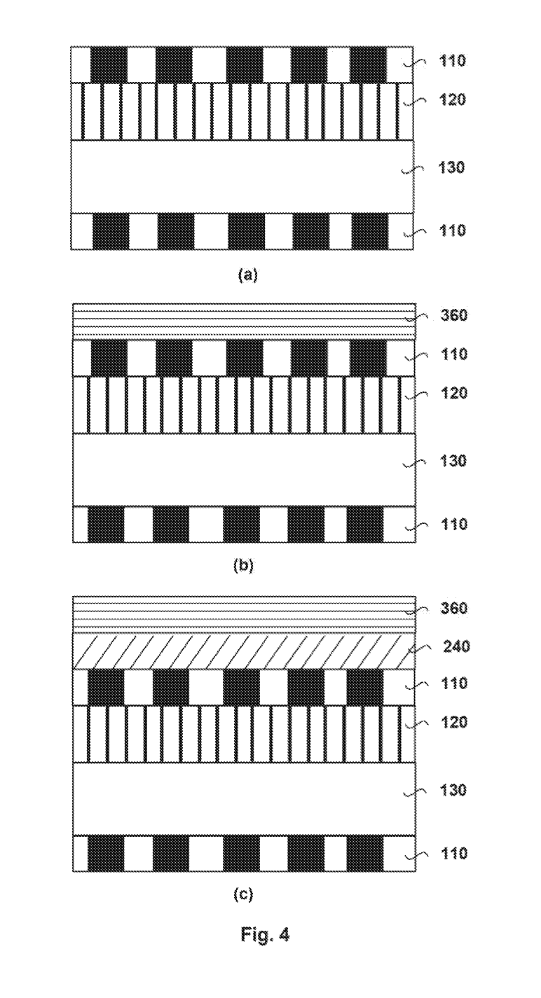

In FIG. 2, when the coat layer 110 is electrophoretic coat (explained below with reference to FIG. 4(a)), the synthetic fibre requires conductive properties, as an example, carbon fibre, carbon nanotubes, aramid fibre and metal fibre. Further, when the coat layer 110 is metal oxide coat (explained below with reference to FIG. 4(a)), FIGS. 2(a) and 2 (c) show the suitable configurations.

As discussed above, the coat 110 can be one of many suitable coats, for example film coat, spray coat, electrophoretic coat and metal oxide coat. Each of these coats 110 will now be discussed.

In the example of a coat 110 being a polymer based transfer film, processes that can be used to apply the coat include in-mould decoration, out-side mould decoration, in-mould film, in-mould label, release film and nano-imprint lithography. Examples of polymer materials that may be used in the transfer film include polycarbonate (PC), polyethylene terephthalate (PET), polyethylene terephthalate glycol (PET-G), polyvinyl chloride (PVC), poly methyl methacrylate (PMMA) polyphenylene sulphide (PPS) and UV ink. The polymer based transfer film may contain inorganic or metallic nano-particles.

The selection of the polymer based transfer film and its application process may depend on desired properties of the film such as visual, tactual, textural effects and functional properties.

In the example of a coat 110 being a spray coat, the spray coat is formed by spray coating the metal surface of the intermediate layer 120, where the topography of the intermediate layer 120 has no influence on the coating weight.

The thickness range of the spray coat may depend on the coating material and the spray system. Thicknesses typically range from 3 to 300 μm.

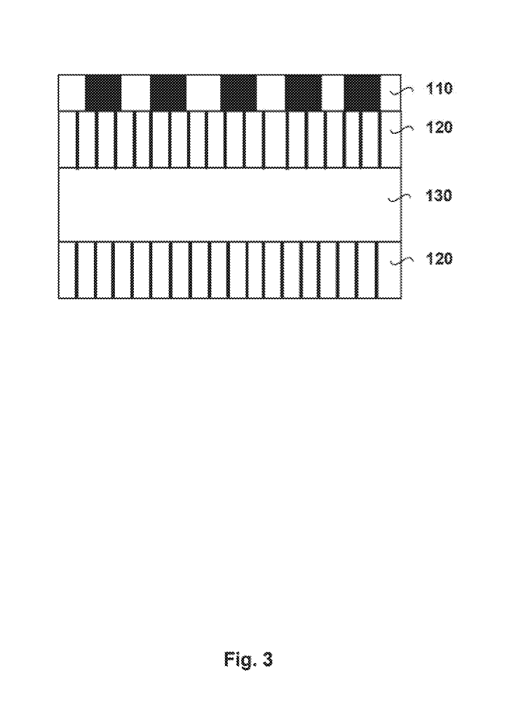

The example casing in FIG. 3 has the substrate layer 130 such as Mg alloys and MgLi alloys that is sandwiched between two intermediate layers 120 such as Al or Al alloys and MgAl alloys. Such configuration is suitable to provide attractive or high performance finishing for both the internal and external side of the casing.

Examples of coating materials suitable for spray coating include thermoplastic coating, thermoset coating, nano-particle coating, metallic coating, UV coating or the combination thereof.

Referring still to FIG. 4(a), the coat 110 can be an electrophoretic coat formed by the electrophoretic deposition onto conductive surfaces, such as substrate 130 and intermediate layers 120. The deposition process is independent of the substrate layer shape or surface morphology.

Typically, the metal to be coated is immersed into a coating solution such as a polyacrylic based formulation. The casing 100 is electrically connected so as to become one of the two electrodes in the coating solution, where the other electrode acts as the counter-electrode. By applying a DC potential between the two electrodes, the colloidal particles suspended in the coating solution migrate under the influence of the applied electric field and are deposited onto the casing 100.

The thickness of the applied electrophoretic coat may depend on the deposition time and the applied voltage potential.

FIG. 4(b) shows an additional coat layer 360 that is further applied onto the surface of the electrophoretic coat of FIG. 4(a). Examples of the additional coat layer include spray coat and film coat.

Referring again to FIGS. 4(a), the coat 110 can be a metal oxide coat and is formed by electrochemical treatment of the surfaces of the metal 120 and 130. The presence of the less reactive light metal 120 such as aluminium and its alloys, ensures a durable, abrasive resistant metal oxide can be formed.

The electrochemical treatment includes applying a voltage greater than the metal oxide coat's dielectric breakdown potential to the metal surface in an electrolytic solution.

The dielectric breakdown potential of a material is the voltage applied via an electric field that the material can withstand without breaking down. When a material such as a metal oxide is treated with a potential greater than its dielectric breakdown potential, the breakdown results in a disruptive discharge through the metal.

The dielectric breakdown potential of a material varies depending on a number of factors, for example the composition, thickness and temperature of the material.

An example of a suitable electrochemical process includes micro-arc oxidation (also known as plasma electrolytic oxidation). Micro-arc oxidation is an electrochemical surface treatment process for generating a coat 110 of oxide on metals 120 and 130.

In one example of micro-arc oxidation, a metal is immersed in a bath of electrolyte, typically an alkali solution such as potassium hydroxide. The casing is electrically connected so as to become one of the electrodes in the electrochemical cell, with the wall of the bath, typically formed of an inert material such as stainless steel, acting as the counter-electrode. A potential is applied between the two electrodes, which may be continuous or pulsing, and direct current or alternating current.

As potentials used in micro-arc oxidation are greater than the dielectric breakdown potential of the forming metal oxide coat, disruptive discharges occur and the resulting high temperature, high pressure plasma modifies the structure of the oxide coat. This results in an oxide coat that is porous and with the oxide in a substantially crystalline form.

In addition, coats 110 of oxide formed in the above manner are conversion coats, converting the existing metal material into the oxide coat. This conversion of the metal provides a good adhesion of the oxide coat to the metal relative to oxide coats deposited on the metal surface as occurs using other methods.

Properties of the oxide coat such as porosity, hardness, colour, conductivity, wear resistance, toughness, corrosion resistance, thickness and adherence to the metal surface can be varied by varying the parameters of the electrochemical treatment. Such parameters include the electrolyte (e.g. temperature and composition), the potential (e.g. pulse or continuous, direct current or alternating current, frequency, duration and voltage) and the processing time.

In one example, the resulting colour of an aluminium oxide coat can be varied by varying the voltage applied. In another example, organic acid can be added to the electrolyte to allow for thicker oxide coats to be formed.

Another electrochemical treatment is anodizing. In anodizing, a reduced voltage is used such that the disruptive discharges observed in micro-arc oxidation do not occur. As a result, the electrolytic solutions used in anodizing are typically corrosive acid solutions which act to form pores through the forming oxide coat to the metal surface, allowing the oxide coat to continue growing.

Referring again to FIG. 4(b) to show another example, where the additional coat layer 360 on the surface of a coat 110 of metal oxide can include film coat, electrophoretic coat and spray coat.

The applicability of an additional coat layer 360 of electrophoretic coat on the coat 110 of surface of the metal oxide is dependent on the thickness of the metal oxide and the voltage potential.

FIG. 4(c) illustrates an example of a casing 100 in FIG. 4(b) with an additional synthetic fibre layer 240 between the coat 110 of metal oxide and the additional coat layer 360. The fibre layer 240 is formed by press forming and further increases the mechanical strength of the casing.

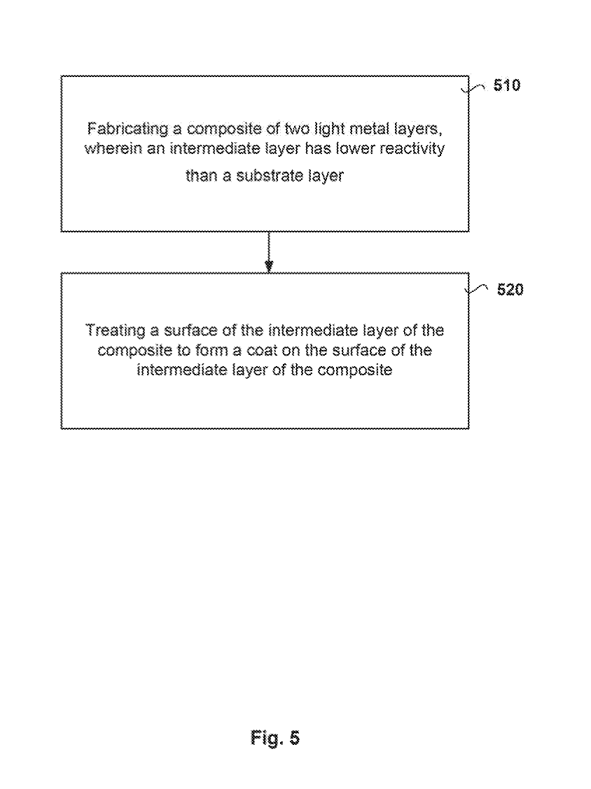

FIG. 5 is a flow diagram illustrating an example method of manufacturing an electrical device casing. The method involves fabricating a composite of two light metals by metal inter-diffusion process 510 and treating a surface of the outer light metal to form a coat 520. Depending on the desired properties of the coat, examples of different surface treatment options include film transfer, spray coating, anodization and micro-arc oxidation can be used.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A casing for a device comprising
a substrate layer of reactive light metal;
an intermediate layer of light metal of lower reactivity than the substrate layer, wherein the intermediate layer is formed on the substrate layer; and
a coat layer formed on the intermediate layer.

2. The casing according to claim 1, wherein an additional synthetic fibre layer is formed between the substrate layer and the intermediate layer.

3. The casing according to claim 1, wherein an additional synthetic fibre layer is formed between the intermediate layer and the coat layer.

4. The casing according to claim 1, wherein the coat layer is a metal oxide coat and an additional coat layer is one of an electrophoretic coat, a film coat, and a spray coat formed on the coat layer.

5. The casing according to claim 4, wherein an additional synthetic fibre layer is formed between the metal oxide coat and the additional coat layer.

6. The casing according to claim 1, wherein the substrate layer is Magnesium Lithium alloys and the intermediate layer is Magnesium Aluminium alloys.

7. The casing according to claim 1, wherein the substrate layer is Magnesium alloys and the intermediate layer is Aluminium, or Aluminium alloys.

8. The casing according to claim 1, wherein an additional synthetic fibre layer is formed on the substrate layer.

9. The casing according to claim 1, wherein the coat layer is an electrophoretic coat formed by electrophoretic deposition of a surface of the intermediate layer.

10. The casing according to claim 1, wherein the coat layer is a metal oxide coat formed by an anodized treatment of a surface of the intermediate layer.

11. The casing according to claim 1, wherein the coat layer is a metal oxide coat formed by a micro-arc oxidation treatment of a surface of the intermediate layer.

12. A casing for electrical devices comprising
an outer finishing;
a middle lamination of light metal of low volatility;
an inner base of light metal of higher volatility than the middle lamination,
wherein the middle lamination is between the inner base and the outer finishing.

13. The casing according to claim 12, wherein the outer finishing is formed by film transfer on a surface of the middle lamination.

14. A method of manufacturing a device casing, the method comprising
fabricating a composite of two light metal layers, wherein an intermediate layer has lower reactivity than a substrate layer, and
treating a surface of the intermediate layer of the composite to form a coat on the surface of the intermediate layer of the composite.

15. The method according to claim 14, wherein treating the surface includes spray coating the surface of the intermediate layer.
